(19) United States
(12) Patent Application Publication
(10) Pub. No.: US 2022/0131339 A1
(43) Pub. Date: Apr. 28, 2022

(54) OPTICAL DEVICE AND METHOD OF MANUFACTURING THE SAME

(71) Applicant: Murata Manufacturing Co., Ltd., Nagaokakyo-shi (JP)

(72) Inventors: Tatsuya OHARA, Nagaokakyo-shi (JP); Hiroyuki NAKANO, Nagaokakyo-shi (JP)

(21) Appl. No.: 17/568,388

(22) Filed: Jan. 4, 2022

Related U.S. Application Data
(63) Continuation of application No. PCT/JP2020/012655, filed on Mar. 23, 2020.

(30) Foreign Application Priority Data
Jul. 9, 2019 (JP) 2019-127788

(51) Int. Cl. H01S 5/026; H01S 5/042

(52) U.S. Cl. CPC H01S 5/0261; H01S 5/0425

(57) ABSTRACT

An optical device is provided that includes at least one optical element, a substrate where a capacitor is arranged and the optical element is disposed thereon, and an interconnection formed on the substrate, with the capacitor and the optical element being electrically connected to each other through the interconnection. The optical device further includes at least one conductive pillar that is larger in height from the substrate than at least than the optical element and is electrically connected to a part of an interconnection. Moreover, an electrode is formed on a surface of each conductive pillar opposite to a surface thereof connected to the part of the interconnection, with the electrode being electrically connected to a circuit board.

### CROSS REFERENCE TO RELATED APPLICATIONS

The present application is a continuation of PCT/JP2020/012655 filed Mar. 23, 2020, which claims priority to Japanese Patent Application No. 2019-127788, filed Jul. 9, 2019, the entire contents of each of which are incorporated herein by reference.

### TECHNICAL FIELD

The present invention relates to an optical device including at least one optical element and a method of manufacturing a plurality of optical devices.

### BACKGROUND

Light detection and ranging (“LiDAR”) has recently be used in an automobile system or a meteorological observation system, for example. LiDAR includes an optical device having a laser diode, a semiconductor switch, a clamp diode, and a power supply condenser.

In particular, LiDAR mounted on a vehicle is desirably compacter by surface mounting of an optical device, such as a laser diode on a substrate. Japanese National Patent Publication No. 2018-525826 (hereinafter “PTL 1”) discloses a laser component (i.e., an optical device) advantageous for surface mounting. The laser component includes a housing having a base section including a top side and an underside, wherein a plurality of electrical soldering contact pads are configured at the underside of the base section. Moreover, the electrical soldering contact pads enable surface mounting of the laser component. A plurality of electrical chip contact pads are configured at the top side of the base section and electrically conductively connect to the soldering contact pads, and a laser chip is arranged in a cavity and connects to the chip contact pads.

In the laser component as described in PTL 1, a laser chip or a control IC is placed in the inside of the housing made of a resin or ceramics and electrically connected through a wire or the like. Therefore, for the laser component, in an assembly step, steps for placing the laser chip or the control IC in the inside of the housing and connecting an electrode of the laser chip or the like to the chip contact pad one by one through a wire or the like are required, which disadvantageously leads to low working efficiency and long working hours.

Modularization of the optical device by placing the laser chip or the control IC in the inside of the housing or a CAN package results in increase in size of the module itself. Therefore, when a module of the optical device is mounted on a circuit board, disadvantageously, mount density is low and an outer geometry of a final product is large.

### SUMMARY OF THE INVENTION

Accordingly, it is an object of the present invention to provide an optical device that achieves reduction in size and high working efficiency. Moreover, a method of manufacturing a plurality of optical devices is also provided.

In an exemplary aspect, an optical device is provided that is mountable on a circuit board. The optical device includes at least one optical element, a substrate where a capacitor is arranged and the optical element is placed, and an interconnection formed on the substrate. Moreover, the capacitor and the optical element are electrically connected to each other through the interconnection, at least one conductive pillar member is larger in height from the substrate at least than the optical element and is electrically connected to a part of the interconnection, and an electrode is formed on a surface of the at least one pillar member opposite to a surface thereof connected to the part of the interconnection, with the electrode being electrically connected to the circuit board.

In addition, a method of manufacturing an optical device is provided for manufacturing an optical device mountable on a circuit board. The method includes forming an interconnection on a substrate where a plurality of capacitors are arranged, placing a plurality of optical elements at prescribed positions on the substrate and electrically connecting the plurality of optical elements and the plurality of capacitors to each other through the interconnection, forming at least one conductive pillar member that is larger in height from the substrate at least than the plurality of optical elements and electrically connected to a part of the interconnection, forming an electrode to electrically be connected to the circuit board on a surface of the at least one pillar member opposite to a surface thereof connected to the part of the interconnection, and dicing the substrate such that each diced substrate includes one of the plurality of optical elements.

According to exemplary aspects of the present invention, an optical device is provided with reduced size because it can be mounted on a circuit board with at least one conductive pillar member being interposed and being larger in height from the substrate than at least the optical element and electrically connected to a part of the interconnection. In the manufacturing method according to the present invention, by electrically connecting at least one pillar member to a part of the interconnection through which the capacitor and the optical element are electrically connected to each other, steps for connection one by one are not required and a plurality of optical devices can be manufactured at high working efficiency.

### BRIEF DESCRIPTION OF DRAWINGS

FIGS. 1(a) and 1(b) are schematic diagrams for illustrating a configuration of an optical device according to the first exemplary embodiment.

FIGS. 2(a) and 2(b) are schematic diagrams for illustrating a configuration of another optical device according to the first exemplary embodiment.

FIG. 3 is a perspective view of the optical device shown in FIG. 2(b).

FIG. 4 is a schematic diagram for illustrating a configuration of an optical device in which an optical component is provided on a substrate.

FIG. 5 is a schematic diagram for illustrating a configuration of an optical device according to the second exemplary embodiment.

FIG. 6 is a schematic diagram for illustrating a configuration of another optical device according to the second exemplary embodiment.

FIG. 7 is a schematic diagram for illustrating a configuration of yet another optical device according to the second exemplary embodiment.

FIG. 8 is a schematic diagram for illustrating a configuration of an optical device according to the third exemplary embodiment.

FIGS. 9(a), 9(b) and 9(c) are schematic diagrams for illustrating a configuration of another optical device according to the third exemplary embodiment.

FIGS. 10(a) and 10(b) are schematic diagrams for illustrating a configuration of an optical device according to the fourth exemplary embodiment.

FIGS. 11(a) and 11(b) are schematic diagrams for illustrating a configuration of an optical device according to the fifth exemplary embodiment.

FIG. 12 is a schematic diagram for illustrating a configuration of another optical device according to the fifth exemplary embodiment.

FIG. 13 is a schematic diagram showing a step of placing an optical element on a substrate in a method of manufacturing an optical device according to the sixth exemplary embodiment.

FIG. 14 is a schematic diagram showing a step of providing a conductive pillar on the substrate in the method of manufacturing an optical device according to the sixth exemplary embodiment.

FIG. 15 is a schematic diagram showing a step of sealing a surface of the substrate with a molding member 70 in the method of manufacturing an optical device according to the sixth exemplary embodiment.

FIG. 16 is a schematic diagram showing a step of forming an electrode on a surface of molding member 70 in the method of manufacturing an optical device according to the sixth exemplary embodiment.

FIG. 17 is a schematic diagram showing a step of dicing into optical devices in the method of manufacturing an optical device according to the sixth exemplary embodiment.

FIGS. 18(a) and 18(b) are schematic diagrams showing a step of mounting an optical device on a circuit board in the method of manufacturing an optical device according to the sixth exemplary embodiment.

### DETAILED DESCRIPTION OF EMBODIMENTS

An optical device according to exemplary embodiments of the present invention will be described below in detail with reference to the drawings. The same or corresponding elements have the same reference characters allotted in the drawings.

### First Exemplary Embodiment

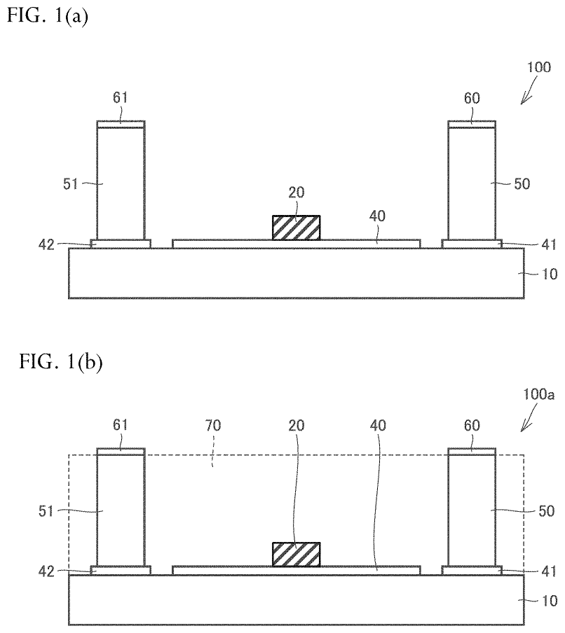

An optical device according to a first exemplary embodiment will be described below with reference to the drawings. FIGS. 1(a) and 1(b) are schematic diagrams for illustrating a configuration of the optical device according to the first embodiment. In particular, FIG. 1(a) shows a side view of an optical device 100 viewed from a side surface of a substrate 10 where an optical element 20 is placed and FIG. 1(b) shows a side view of an optical device 100a in which a surface of substrate 10 where optical element 20 is placed is sealed with a molding member 70.

In the optical device 100 shown in FIG. 1(a), a capacitor (not shown) is arranged on or in the inside of substrate 10, and an interconnection 40 is formed on a surface of substrate 10. The capacitor and optical element 20 are electrically connected to each other through interconnection 40 or the like to form a circuit. In general, it is noted that the arrangement and a size of optical element 20 and interconnection 40 shown in FIG. 1(a) do not represent arrangement and a size in actual optical device 100. This is also applicable to the drawings below. Moreover, a conductive pillar 50, which is a conductive pillar member, is provided on a part of an interconnection 41 and a conductive pillar 51, which is a conductive pillar member, is provided on a part of an interconnection 42.

Conductive pillars 50 and 51 are provided substantially perpendicularly to the surface of substrate 10 and provided at positions where they do not cut off an optical path of optical element 20. In conductive pillars 50 and 51, electrodes 60 and 61, which can be provided for electrical connection to an external circuit board, are formed on surfaces opposite to surfaces thereof connected to parts of interconnections 41 and 42, respectively. Electrodes 60 and 61 are formed, for example, by plating or vapor deposition on respective one surfaces of conductive pillars 50 and 51.

Though FIG. 1(a) shows only two conductive pillars, conductive pillars are provided at four corners of substrate 10 in the exemplary embodiment. Moreover, conductive pillars 50 and 51 are larger in height from substrate 10 at least than optical element 20. Therefore, even when optical device 100 is flip-chip mounted on a circuit board to connect electrodes 60 and 61 to the circuit board, optical element 20 is not in contact with the circuit board.

Substrate 10 is, for example, a silicon substrate. As discussed above, a capacitor is arranged on or in the inside of substrate 10. Specifically, a configuration in which a condenser is placed on a surface of the silicon substrate or a configuration in which a semiconductor capacitor is formed in the inside of the silicon substrate is applicable. Substrate 10 is not limited to the silicon substrate and may be a ceramic substrate (for example, low temperature co-fired ceramics (LTCC)) or a resin substrate (for example, a glass composite substrate, a glass epoxy substrate, or an FR-4 substrate). Moreover, substrate 10 may be a special substrate with surface irregularities.

Optical element 20 is, for example, such a solid light emitting element that, by feeding electricity to a solid substance, the substance itself emits light, and includes a light emitting diode (LED), a laser diode (LD), and an electroluminescence element (EL). Optical element 20 includes a light emitter (not shown) that emits light in a direction in parallel to the surface of substrate 10. Therefore, optical device 100 can be configured to output light in the direction in parallel to the surface of substrate 10. In one exemplary aspect, optical element 20 may be vertical cavity surface emitting laser (VCSEL) that emits light perpendicularly to the surface of substrate 10.

Moreover, it is noted that optical element 20 is not limited to the light emitting element that emits light, but may be a light reception element that receives light. Examples of the light reception element include a phototransistor, a photodiode, an avalanche photodiode, a photoconductive cell, and an image sensor.

Optical element 20 has one electrode (for example, an anode) connected to an electrode formed in interconnection 40 and has the other electrode (for example, a cathode) connected to another electrode formed in interconnection 40 different from interconnection 40 to which the one electrode is connected. The capacitor and optical element 20 are electrically connected to each other through interconnection 40. Such materials as Au, Al, and Cu are employed for materials for interconnection 40.

Moreover, conductive pillars 50 and 51 are made from metal pins formed in a columnar shape. Such materials as Au, Al, and Cu are employed for materials for the metal pins. Conductive pillars 50 and 51 may be formed by plating other than being made from metal pins.

In optical device 100a shown in FIG. 1(b), the surface of substrate 10 where optical element 20 is placed is sealed with molding member 70. In an exemplary aspect, molding member 70 may be formed of an organic material such as a silicon-based resin, an epoxy-based resin, an acrylic resin, a polyimide-based resin, or a phenol-based resin, or a liquid filler composed of an inorganic material such as liquid glass. Preferably, molding member 70 should be made of a material transparent to a wavelength of light emitted or received by optical element 20 such as a material transparent to light in a band from visible light to infrared light. Molding member 70 should only be a member through which a wavelength of light emitted or received by optical element 20 passes at least on an optical path of the light, without being limited to molding member 70 composed of a transparent material in its entirety that covers the surface of substrate 10 where optical element 20 and conductive pillars 50 and 51 are provided.

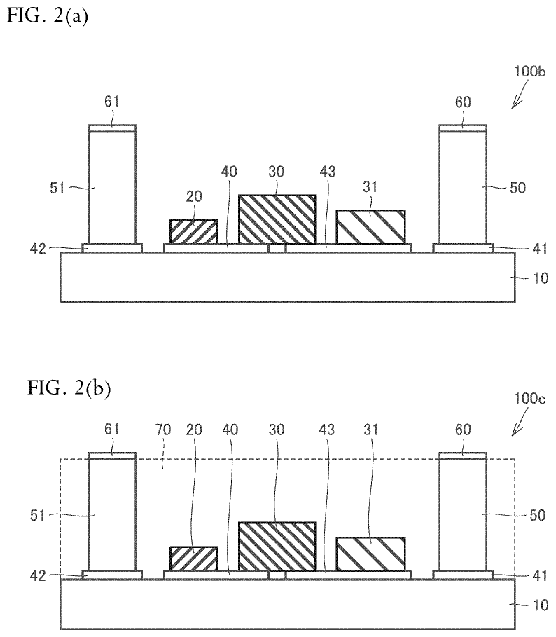

An element arranged on the substrate is not limited to the optical element alone, but may include a switching element for control of power feed to the optical element and a control element for control of light emission by the optical element. FIGS. 2(a) and 2(b) are schematic diagrams for illustrating a configuration of another optical device according to the first embodiment. In particular, FIG. 2(a) shows a side view of an optical device 100b viewed from the side surface of substrate 10 where optical element 20 is placed and FIG. 2(b) shows a side view of an optical device 100c in which the surface of substrate 10 where optical element 20 is placed is sealed with molding member 70. Features of optical devices 100b and 100c shown in FIGS. 2(a) and 2(b) that are the same as those of optical devices 100 and 100a shown in FIGS. 1(a) and 1(b) have the same reference characters allotted and detailed description will not be repeated.

In optical device 100b shown in FIG. 2(a), at least optical element 20 and a semiconductor switch 30 are arranged on substrate 10. In optical device 100b, a control IC 31 that controls semiconductor switch 30 is further arranged on substrate 10. A capacitor, optical element 20, semiconductor switch 30, and control IC 31 arranged on substrate 10 are electrically connected to one another through interconnection 40 and an interconnection 43 and they form a circuit. Arrangement and a size of optical element 20, semiconductor switch 30, control IC 31, interconnection 40, and interconnection 43 shown in FIG. 2 (a) do not represent arrangement and a size in actual optical device 100b.

Conductive pillar 50, which is a conductive pillar member, is provided on a part of interconnection 41 and conductive pillar 51, which is a conductive pillar member, is provided on a part of interconnection 42. Conductive pillars 50 and 51 are provided substantially perpendicularly to the surface of substrate 10 and provided at positions where they do not cut off the optical path of optical element 20.

In conductive pillars 50 and 51, electrodes 60 and 61 for electrical connection to an external circuit board are formed on surfaces opposite to surfaces connected to parts of interconnections 41 and 42, respectively. Electrodes 60 and 61 are formed, for example, by plating or vapor deposition on respective one surfaces of conductive pillars 50 and 51.

Semiconductor switch 30 is a switching element, and implemented, for example, by a silicon MOSFET or a GaN FET. Moreover, semiconductor switch 30 has one electrode (for example, a drain electrode) connected to an electrode of interconnection 40 and has the other electrode (for example, a source electrode) connected to an electrode of interconnection 43. As further shown, semiconductor switch 30 and control IC 31 are electrically connected to each other through interconnection 43. According to exemplary aspects, such materials as Au, Al, and Cu can be used for materials for interconnection 43.

Control IC 31 is an IC circuit that controls semiconductor switch 30, and implemented, for example, by an application specific integrated circuit (ASIC) or a field-programmable gate array (FPGA).

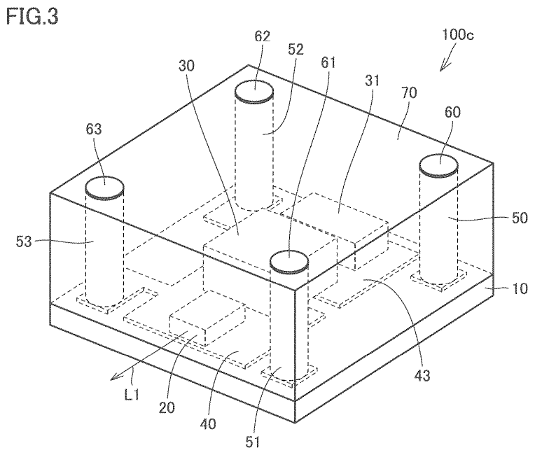

In optical device 100c shown in FIG. 2(b), the surface of substrate 10 where optical element 20 is placed is sealed with molding member 70. FIG. 3 is a perspective view of optical device 100c shown in FIG. 2(b). As shown in FIG. 3, conductive pillars 50 to 53 are provided on the surface of substrate 10 where optical element 20 is provided, and arranged not to cut off an optical path L1 of optical element 20. In connecting optical device 100c to an external circuit board, conductive pillars 50 to 53 are desirably provided at four corners of substrate 10 in consideration of stability in connection between optical device 100c and the circuit board.

Conductive pillars 50 to 53 include respective surfaces protruding from molding member 70, and electrodes 60 and 63 are formed by plating the surfaces. Optical device 100c can be mounted on the circuit board by flip-chip mounting by being connected to the circuit board at the surfaces where electrodes 60 to 63 are formed. Thus, optical device 100c is larger in height from substrate 10 at least than optical element 20 and mounted on the circuit board with conductive pillars 50 to 53 electrically connected to respective parts of the interconnections being interposed. Since an electrode or an interconnection for connection to the circuit board does not have to separately be provided, optical device 100c can be reduced in size.

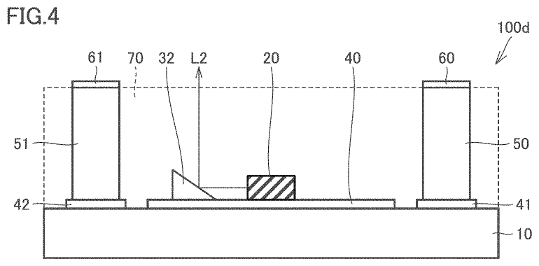

Though optical devices 100b and 100c configured such that optical element 20, semiconductor switch 30, and control IC 31 are arranged on substrate 10 are described, a component arranged on substrate 10 is not limited thereto. Examples of components arranged on substrate 10 include a diode, a capacitor, a resistor, and a coil. In addition, an optical component that changes the optical path of optical element 20 may be provided on substrate 10. FIG. 4 is a schematic diagram for illustrating a configuration of an optical device in which an optical component is provided on substrate 10. The features of an optical device 100d shown in FIG. 4 that are the same as those of optical device 100a shown in FIG. 1(b) have the same reference characters allotted and detailed description will not be repeated.

In optical device 100d shown in FIG. 4, an optical component 32 that changes the optical path of light emitted or received by optical element 20 is arranged on substrate 10. Examples of optical component 32 include a mirror and a prism. Optical component 32 changes the optical path of optical element 20 in parallel to the surface of substrate 10 to an optical path L2 perpendicular to the surface of substrate 10. In optical device 100d, the optical path of light emitted or received by optical element 20 can thus freely be changed by optical component 32. Though FIG. 4 illustrates the optical device in which the surface of substrate 10 where optical element 20 is placed is sealed with molding member 70, the optical device in which the surface of substrate 10 is not sealed with molding member 70 may be applicable.

As set forth above, the optical device according to the present embodiment is optical device 100 mountable on a circuit board. Optical device 100 includes at least one optical element 20, substrate 10 where a capacitor is arranged and optical element 20 is placed, and interconnection 40 formed on substrate 10, the capacitor and optical element 20 being electrically connected to each other through interconnection 40. Optical device 100 further includes at least one conductive pillar 50, 51 larger in height from substrate 10 at least than optical element 20 and electrically connected to a part of interconnection 41, 42, and electrode 60, 61 formed on the surface of at least one conductive pillar 50, 51 opposite to the surface thereof connected to the part of interconnection 41, 42, electrode 60, 61 being electrically connected to the circuit board.

Optical device 100d according to the present embodiment can thus be reduced in size because it can be mounted on a circuit board with at least one conductive pillar 50, 51 being interposed, at least one conductive pillar 50, 51 being larger in height from substrate 10 at least than optical element 20 and electrically connected to a part of interconnection 41, 42.

Optical device 100d according to the present embodiment may further include molding member 70 that covers the surface of substrate 10 where optical element 20 and at least one conductive pillar 50, 51 are provided. Preferably, molding member 70 should only be a member through which a wavelength of light emitted or received by optical element 20 passes at least on an optical path of the light. Molding member 70 may be a member that covers a surface of substrate 10 where optical element 20 and at least one conductive pillar 50, 51 are provided, the member being transparent to a wavelength of light emitted or received by optical element 20. Optical device 100d can thus protect optical element 20 with molding member 70 while the optical path of light emitted or received by optical element 20 is secured.

In optical devices 100b and 100c according to the present embodiment, at least one of semiconductor switch 30 for control of power feed to optical element 20 and control IC 31 for control of light emission by optical element 20 may be arranged on substrate 10. Various types of circuitry can thus be adopted for optical devices 100b and 100c.

In optical device 100d according to the present embodiment, optical component 32 that changes the optical path of light emitted or received by optical element 20 may be arranged on substrate 10. Optical device 100d can thus change the optical path of light emitted or received by optical element 20 by means of optical component 32.

### Second Exemplary Embodiment

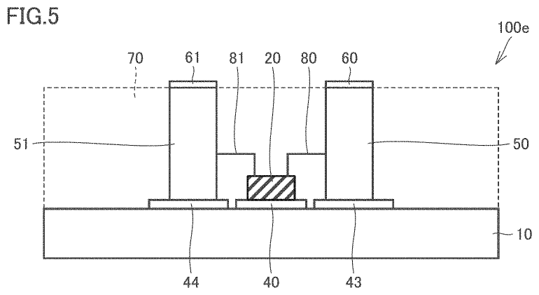

In the first embodiment, as shown in FIG. 1(a), optical device 100 is configured such that at least one conductive pillar 50, 51 is electrically connected to a part of interconnection 41, 42 and at least one conductive pillar 50, 51 and optical element 20 are electrically connected to each other is described. In the second exemplary embodiment, an optical device in which a conductive pillar and optical element 20 are electrically connected to each other in a different configuration and an optical device in which the conductive pillar itself is different in shape will be described. FIG. 5 is a schematic diagram for illustrating a configuration of an optical device 100e according to the second embodiment. FIG. 5 shows a side view of optical device 100e viewed from the side surface of substrate 10 where optical element 20 is placed. It is noted that features of optical device 100e shown in FIG. 5 the same as those of optical device 100 shown in FIG. 1(a) have the same reference characters allotted and detailed description will not be repeated.

In optical device 100e shown in FIG. 5, a capacitor (not shown) is arranged on or in the inside of substrate 10, and interconnection 40 is formed on the surface of substrate 10. The capacitor and optical element 20 are electrically connected to each other through interconnection 40 or the like and they form a circuit. Conductive pillar 50, which is a conductive pillar member, is provided on interconnection 43 not electrically connected to interconnection 40 and conductive pillar 51, which is a conductive pillar member, is provided on an electrode 44 not electrically connected to interconnection 40.

Conductive pillars 50 and 51 are provided substantially perpendicularly to the surface of substrate 10 and provided at positions where they do not cut off the optical path of optical element 20. Moreover, conductive pillar 50 is electrically connected to optical element 20 through a wire 80 and conductive pillar 51 is electrically connected to optical element 20 through a wire 81. In conductive pillars 50 and 51, electrodes 60 and 61 for electrical connection to an external circuit board are formed on surfaces opposite to surfaces thereof connected to interconnection 43 and electrode 44, respectively. According to an exemplary aspect, electrodes 60 and 61 are formed, for example, by plating or vapor deposition on respective one surfaces of conductive pillars 50 and 51. In optical device 100e, the surface of substrate 10 where optical element 20 is placed is sealed with molding member 70. In an alternative aspect, only one of conductive pillar 50 and conductive pillar 51 can be provided on substrate 10.

Though optical element 20 and substrate 10 may generally be connected to each other through a wire, the wire is directly connected to each of conductive pillars 50 and 51. It is noted that the method of connecting conductive pillars 50 and 51 and wires 80 and 81 to each other is not particularly limited, and they are connected, for example, by adhesion using a conductive resin. In optical device 100e, conductive pillars 50 and 51 are electrically connected to optical element 20 through wires 80 and 81. In other words, in optical device 100e, at least one of a plurality of conductive pillars is directly electrically connected to optical element 20 through the wire, instead of being electrically connected to a part of the interconnection. In optical device 100e, an equivalent series inductance (ESL) in the circuit can thus be reduced. Though FIG. 5 illustrates the optical device in which the surface of substrate 10 where optical element 20 is placed is sealed with molding member 70, the optical device in which the surface of substrate 10 is not sealed with molding member 70 may be applicable.

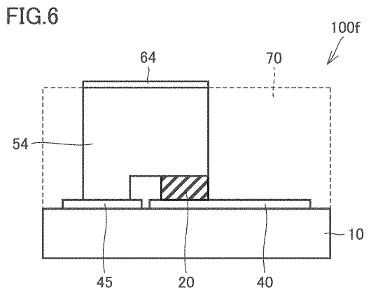

A differently configured optical device will be described. In particular, FIG. 6 is a schematic diagram for illustrating a configuration of another optical device 100f according to the second embodiment. FIG. 6 shows a side view of optical device 100f viewed from the side surface of substrate 10 where optical element 20 is placed. Features of optical device 100f shown in FIG. 6 the same as those of optical device 100 shown in FIG. 1(a) have the same reference characters allotted and detailed description will not be repeated.

In optical device 100f shown in FIG. 6, a capacitor (not shown) is arranged on or in the inside of substrate 10, and interconnection 40 is formed on the surface of substrate 10. The capacitor and optical element 20 are electrically connected to each other through interconnection 40 or the like and they form a circuit. A conductive pillar 54 which is a conductive pillar member is provided on an electrode 45 not electrically connected to interconnection 40.

According to the exemplary embodiment, conductive pillar 54 is provided substantially perpendicularly to the surface of substrate 10 and provided at a position where it does not cut off the optical path of optical element 20. Moreover, conductive pillar 54 includes a portion extending toward optical element 20 (e.g., to overhand and cover at least a portion thereof) and this portion is electrically connected to optical element 20. In conductive pillar 54, an electrode 64 for electrical connection to an external circuit board is formed on a surface opposite to a surface thereof connected to electrode 45. Electrode 64 is formed, for example, by plating or vapor deposition on one surface of conductive pillar 54. Moreover, in optical device 100f, the surface of substrate 10 where optical element 20 is placed is sealed with molding member 70.

In optical device 100f, optical element 20, interconnection 40, and electrode 64 are directly connected to one another through conductive pillar 54. In other words, in optical device 100f, at least one of a plurality of conductive pillars is partially directly electrically connected to optical element 20 instead of being electrically connected to a part of the interconnection. Since optical element 20 and conductive pillar 54 can thus be connected to each other without using a wire in optical device 100f, the optical device can be inexpensive and the number of steps in manufacturing can be reduced. Though FIG. 6 illustrates the optical device in which the surface of substrate 10 where optical element 20 is placed is sealed with molding member 70, the optical device in which the surface of substrate 10 may not be sealed with molding member 70 in an alternative aspect.

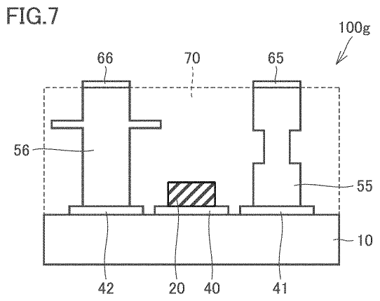

A further differently configured optical device will be described. In particular, FIG. 7 is a schematic diagram for illustrating a configuration of yet another optical device 100g according to the second embodiment. FIG. 7 shows a side view of optical device 100g viewed from the side surface of substrate 10 where optical element 20 is placed. It is again noted that features of optical device 100g shown in FIG. 7 the same as those of optical device 100 shown in FIG. 1(a) have the same reference characters allotted and detailed description will not be repeated.

In optical device 100g shown in FIG. 7, a capacitor (not shown) is arranged on or in the inside of substrate 10, and interconnection 40 is formed on the surface of substrate 10. The capacitor and optical element 20 are electrically connected to each other through interconnection 40 or the like and they form a circuit. A conductive pillar 55, which is a conductive pillar member, is provided on a part of interconnection 41 and a conductive pillar 56, which is a conductive pillar member, is provided on a part of interconnection 42.

Conductive pillars 55 and 56 are provided substantially perpendicularly to the surface of substrate 10 and provided at positions where they do not cut off the optical path of optical element 20. In conductive pillars 55 and 56, electrodes 65 and 66 for electrical connection to an external circuit board are formed on surfaces opposite to surfaces thereof connected to parts of interconnections 41 and 42, respectively. Electrodes 65 and 66 are formed, for example, by plating or vapor deposition on respective one surfaces of conductive pillars 55 and 56. In optical device 100g, the surface of substrate 10 where optical element 20 is placed is sealed with molding member 70.

In optical device 100g, a recess is provided in conductive pillar 55 and a protrusion is provided on conductive pillar 56. In other words, in optical device 100g, at least one of a plurality of conductive pillars 55 and 56 includes a portion different in cross-sectional shape in a surface in parallel to the surface of substrate 10. Moreover, in optical device 100g, coming-off of conductive pillars 55 and 56 from molding member 70 can thus be avoided.

### Third Exemplary Embodiment

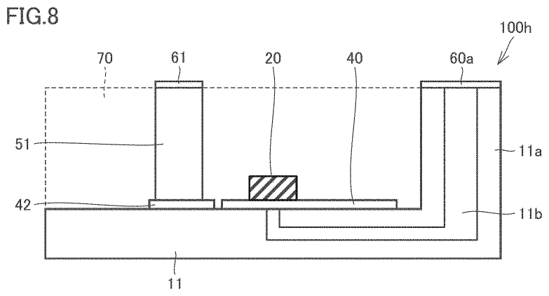

In the first embodiment, as shown in FIG. 1(a), optical device 100 configured such that at least one conductive pillar 50, 51 is provided substantially perpendicularly to the surface of substrate 10 is described. In the third exemplary embodiment, an optical device including a differently configured substrate will be described. FIG. 8 is a schematic diagram for illustrating a configuration of an optical device 100h according to the third exemplary embodiment. FIG. 8 shows a side view of optical device 100h viewed from a side surface of a substrate 11 where optical element 20 is placed. Features of optical device 100h shown in FIG. 8 the same as those of optical device 100 shown in FIG. 1(a) have the same reference characters allotted and detailed description will not be repeated.

In optical device 100h shown in FIG. 8, a capacitor (not shown) is arranged on or in the inside of substrate 11, and interconnection 40 is formed on a surface of substrate 11. As further shown, substrate 11 has a cross-section in an L shape and includes a portion 11a bent substantially perpendicularly to the surface of substrate 11 where interconnection 40 is formed. The shape of substrate 11 is by way of example and may be in another shape such as a concave shape. In the inside of substrate 11, an internal interconnection 11b electrically connected to interconnection 40 is provided. The capacitor and optical element 20 are electrically connected to each other through interconnection 40 or the like and they form a circuit. Moreover, conductive pillar 51, which is a conductive pillar member, is provided on a part of interconnection 42.

Conductive pillar 51 is provided substantially perpendicularly to the surface of substrate 11 and provided at a position where it does not cut off the optical path of optical element 20. Moreover, conductive pillar 51 substantially has the same height as bent portion 11a. In conductive pillar 51, electrode 61 for electrical connection to an external circuit board is formed on a surface opposite to a surface thereof connected to a part of interconnection 42. Bent portion 11a has an electrode 60a formed on the same surface where electrode 61 is formed. Moreover, electrode 60a is electrically connected to internal interconnection 11b. Electrodes 60a and 61 are formed, for example, by plating or vapor deposition on respective one surfaces of bent portion 11a and conductive pillar 51. In optical device 100h, the surface of substrate 11 where optical element 20 is placed is sealed with molding member 70.

In optical device 100h, substrate 11 includes bent portion 11a, and optical element 20 is placed by forming interconnection 40 in another portion of substrate 11. In optical device 100h, electrode 60a is formed in bent portion 11a and electrical connection to a circuit board is established by electrode 60a. In other words, in optical device 100h, a part of substrate 11 is at least as high as at least one conductive pillar, and electrode 60a formed in a part of substrate 11 and optical element 20 are electrically connected to each other through internal interconnection 11b provided within the substrate. In optical device 100h, at least one of the conductive pillars is thus not required, and the number of components to be mounted can be reduced in this embodiment. Though FIG. 8 illustrates the optical device in which the surface of substrate 11 where optical element 20 is placed is sealed with molding member 70, the optical device in which the surface of substrate 11 is not sealed with molding member 70 can be provided in an alternative aspect.

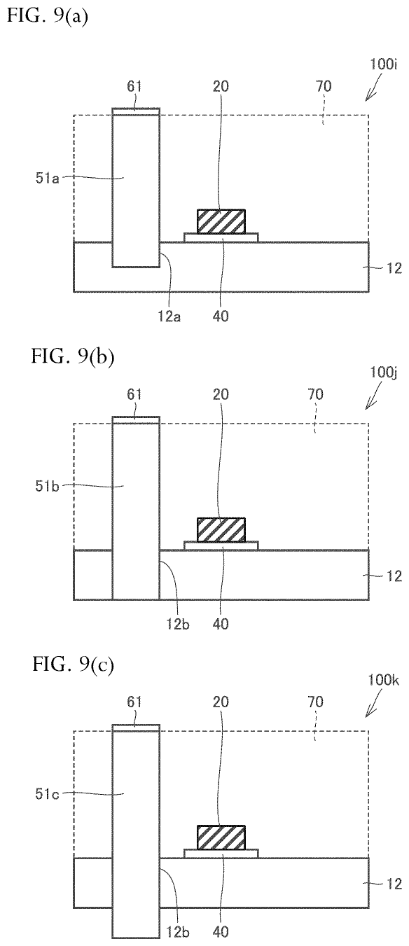

A differently configured optical device will be described. Specifically, FIGS. 9(a), 9(b) and 9(c) are schematic diagrams for illustrating a configuration of another optical device according to the third embodiment. In an optical device 100i shown in FIG. 9(a), a part of a conductive pillar 51a is inserted (or otherwise formed or disposed) in a recess 12a provided in a substrate 12 and conductive pillar 51a is provided substantially perpendicularly to a surface of substrate 12. In an optical device 100j shown in FIG. 9(b), a conductive pillar 51b is inserted in a through hole 12b provided in substrate 12, and conductive pillar 51b is provided substantially perpendicularly to the surface of substrate 12. In an optical device 100k shown in FIG. 9(c), a conductive pillar 51c passes through the through hole 12b provided in substrate 12, and conductive pillar 51c is provided substantially perpendicularly to the surface of substrate 12. Conductive pillars 51a to 51c shown in these figures may each have a portion different in cross-sectional shape in a surface in parallel to the surface of substrate 12 as shown in FIG. 7.

FIGS. 9(a)-(c) show a side view of each of optical devices 100i to 100k viewed from the side surface of substrate 12 where optical element 20 is placed. Features of optical devices 100i to 100k shown are the same as those of optical device 100 shown in FIG. 1(a) have the same reference characters allotted and detailed description will not be repeated.

In each of optical devices 100i to 100k shown in FIGS. 9(a)-(c), a capacitor (not shown) is arranged on or in the inside of substrate 12, and interconnection 40 is formed on the surface of substrate 12. The capacitor and optical element 20 are electrically connected to each other through interconnection 40 or the like and they form a circuit. In conductive pillar 51a, electrode 61 for electrical connection to an external circuit board is formed on a surface opposite to a portion inserted in recess 12a. In conductive pillars 51b and 51c, electrode 61 for electrical connection to an external circuit board is formed on a surface opposite to a portion inserted in through hole 12b. Electrode 61 is formed, for example, by plating or vapor deposition on one surface of each of conductive pillars 51a to 51c. In optical devices 100i to 100k, the surface of substrate 12 where optical element 20 is placed is sealed with molding member 70.

Optical devices 100i to 100k are not configured to provide a conductive pillar on the surface of the substrate but at least one conductive pillar 51a to 51c among the plurality of conductive pillars is inserted in recess 12a or through hole 12b provided in substrate 12. In optical devices 100i to 100k, conductive pillars 51a to 51c can thus be provided in substrate 12 in various structures. Though FIGS. 9(a)-(c) illustrates the optical device in which the surface of substrate 12 where optical element 20 is placed is sealed with molding member 70, the optical device in which the surface of substrate 12 is not sealed with molding member 70 may be applicable.

### Fourth Exemplary Embodiment

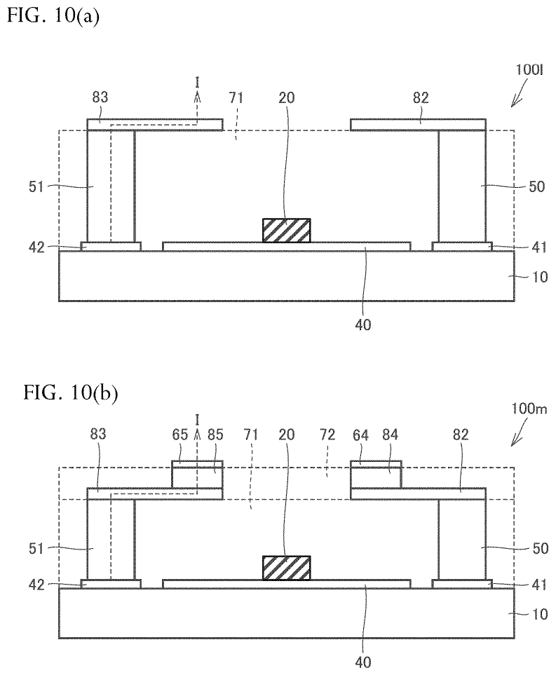

In the first embodiment, as shown in FIG. 1(b), optical device 100a configured such that electrodes 60 and 61 are provided on the surface of molding member 70 is described. In the fourth exemplary embodiment, an optical device is configured such that an interconnection rather than an electrode is provided on a surface of a molding member will be described. In particular, FIGS. 10(a) and 10(b) are schematic diagrams for illustrating a configuration of optical device 100 according to the fourth embodiment. In an optical device 100l shown in FIG. 10(a), an interconnection 82 electrically connected to conductive pillar 50 and an interconnection 83 electrically connected to conductive pillar 51 are provided on a surface of a molding member 71 with which the surface of substrate 10 where optical element 20 is placed is sealed.

In an optical device 100m shown in FIG. 10(b), a conductive pillar 84 is provided on interconnection 82 that is provided on the surface of molding member 71 and a conductive pillar 85 is provided on interconnection 83. In optical device 100m, interconnections 82 and 83 and conductive pillars 84 and 85 are sealed with a molding member 72. FIGS. 10(a)-(b) show side views of each of optical devices 100l and 100m viewed from the side surface of substrate 10 where optical element 20 is placed. Features of optical devices 100l and 100m shown in FIGS. 10(a) and 10(b) the same as those of optical device 100 shown in FIG. 1(a) have the same reference characters allotted and detailed description will not be repeated.

In optical devices 100l and 100m, a capacitor (not shown) is arranged on or in the inside of substrate 10, and interconnection 40 is formed on the surface of substrate 10. The capacitor and optical element 20 are electrically connected to each other through interconnection 40 or the like and they form a circuit. Conductive pillar 50, which is a conductive pillar member, is provided on a part of interconnection 41 and conductive pillar 51, which is a conductive pillar member, is provided on a part of interconnection 42.

Conductive pillars 50 and 51 are provided substantially perpendicularly to the surface of substrate 10 and provided at positions where they do not cut off the optical path of optical element 20. Conductive pillars 84 and 85 shown in FIG. 10(b) are provided substantially perpendicularly to the surface of substrate 10 and electrodes 64 and 65 for electrical connection to an external circuit board are formed on surfaces opposite to surfaces thereof connected to interconnections 82 and 83, respectively. Electrodes 64 and 65 are formed, for example, by plating or vapor deposition on respective one surfaces of conductive pillars 84 and 85.

In optical device 100m shown in FIG. 10(b), lower conductive pillars 50 and 51 and upper conductive pillars 84 and 85 may be made of an identical material or of different materials. Moreover, in optical device 100m, lower molding member 71 and upper molding member 72 may be made of an identical material or of different materials. A process for manufacturing optical device 100m is performed in an order of formation of lower conductive pillars 50 and 51 followed by formation of lower molding member 71, formation of interconnections 82 and 83 on the surface of formed molding member 71, upper conductive pillars 84 and 85, upper molding member 72, and plating of electrodes 64 and 65.

In optical device 100l, interconnections 82 and 83 are provided on the surface of formed molding member 71. In optical device 100m, upper conductive pillars 84 and 85 are further provided on interconnections 82 and 83 and sealed with molding member 72, and thereafter electrodes 64 and 65 are formed. In other words, in optical device 100m, the molding member is formed in a plurality of layers, and an in-mold interconnection 82, 83 electrically connected to at least one conductive pillar 84, 85 is formed between one layer and another layer. Thus, in optical devices 100l and 100m, a position of a conductive pillar is not limited by a position of an electrode of a circuit board for mount, and a flow I of a current shown in FIGS. 10(a) and (b) can be changed by interconnections 82, 83 in conformity with a position of the electrode on the circuit board for mount.

### Fifth Exemplary Embodiment

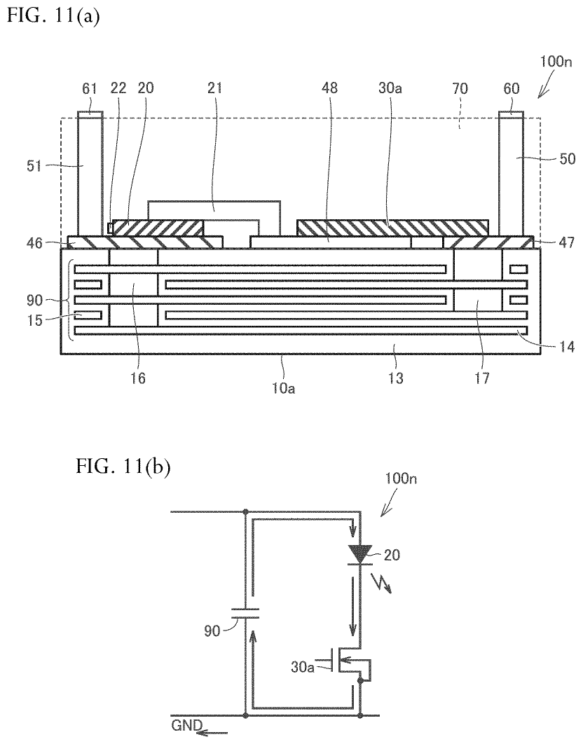

In the first embodiment, a capacitor is described as being arranged on or in the inside of substrate 10. In the fifth exemplary embodiment, in particular, a configuration in which a capacitor is arranged in the inside of the substrate will specifically be described. Specifically FIGS. 11(a) and 11(b) are schematic diagrams for illustrating a configuration of an optical device 100n according to the fifth embodiment. FIG. 11(a) shows a side view of optical device 100n viewed from a side surface of a substrate 10a where optical element 20 is placed and FIG. 11(b) is a circuit diagram of optical device 100n. It is noted that the features of optical device 100n shown in FIG. 11(a) are the same as those of optical device 100a shown in FIG. 1(b) and have the same reference characters allotted so detailed description will not be repeated.

As shown, optical device 100n shown in FIG. 11(a) includes substrate 10a within which a condenser 90 which is a capacitor is arranged, optical element 20 placed on an outer surface of substrate 10a, and a semiconductor switch 30a. Condenser 90 is a power supply condenser and implemented by a multilayer ceramic condenser. Therefore, condenser 90 is implemented by a multilayer body in which a plurality of internal electrodes 14 and 15 for obtaining a capacitance and a dielectric ceramic layer 13 are alternately layered.

As shown in FIG. 11(a), condenser 90 provided in the inside of substrate 10a form via conductors 16 and 17 that pass through the multilayer body. An interconnection 46 formed on the surface of substrate 10a and layered internal electrodes 14 are electrically connected to each other through via conductor 16. Though internal electrode 14 is electrically connected to via conductor 16, it is not electrically connected to via conductor 17. An interconnection 47 formed on the outer surface of substrate 10a and layered internal electrodes 15 are electrically connected to each other through via conductor 17. Though not shown, internal electrode 15 is electrically connected to via conductor 17 but not electrically connected to via conductor 16.

Optical element 20 is such a light emitting element that, by feeding electricity to a solid substance, the substance itself emits light, and examples thereof include a light emitting diode (LED), a laser diode (LD), and an electroluminescence element (EL). Optical element 20 includes a light emitter 22 that emits light in a direction in parallel to the outer surface of condenser 90. Therefore, optical device 100n can provide output of light in the direction in parallel to the outer surface of condenser 90. According to an exemplary aspect, optical element 20 has one electrode (for example, an anode) connected to interconnection 46 and has the other electrode (for example, a cathode) electrically connected to an interconnection 21. Optical element 20 and an interconnection 48 are electrically connected to each other through interconnection 21.

Moreover, semiconductor switch 30a has one electrode (for example, a drain electrode) and the other electrode (for example, a source electrode) formed on the same surface. Therefore, semiconductor switch 30a has one electrode (for example, the drain electrode) connected to interconnection 48 and has the other electrode (for example, the source electrode) electrically connected to an interconnection 47.

Conductive pillar 50, which is a conductive pillar member, is provided on interconnection 47 and conductive pillar 51, which is a conductive pillar member, is provided on interconnection 46. Conductive pillars 50 and 51 are provided substantially perpendicularly to the surface of substrate 10a and provided at positions where they do not cut off the optical path of optical element 20. In conductive pillars 50 and 51, electrodes 60 and 61 for electrical connection to an external circuit board are formed on surfaces opposite to surfaces thereof connected to interconnections 47 and 46, respectively. Electrodes 60 and 61 are formed, for example, by plating or vapor deposition on respective one surfaces of conductive pillars 50 and 51. In optical device 100n, the surface of substrate 10a where optical element 20 is placed is sealed with molding member 70.

FIG. 11(b) is a circuit diagram of optical device 100n. In the circuit diagram shown in FIG. 11(b), one electrode of condenser 90 and one electrode (for example, the anode) of optical element 20 are connected to each other, and the other electrode (for example, the cathode) of optical element 20 and semiconductor switch 30a are connected to each other. Semiconductor switch 30a has one electrode (for example, the drain electrode) connected to optical element 20 and has the other electrode (for example, the source electrode) connected to the other electrode of condenser 90 and a GND line.

In optical device 100n, optical element 20 and semiconductor switch 30a are placed on the outer surface of condenser 90, and condenser 90, optical element 20, and semiconductor switch 30a are connected in series through interconnections 46, 47, and 48 as shown in FIGS. 2(a) and 2(b).

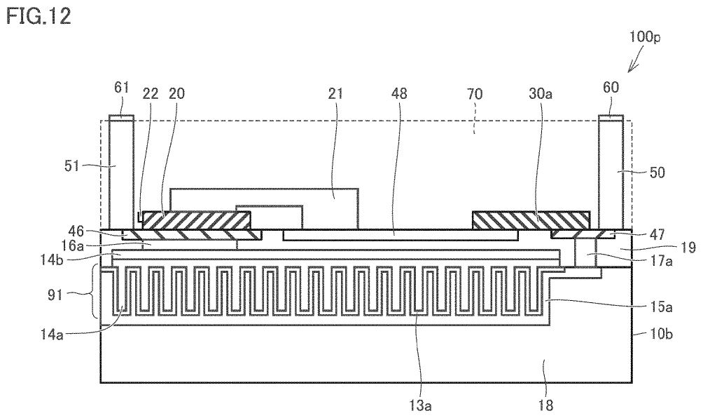

The configuration in which the capacitor is arranged in the inside of the substrate is not limited to the configuration of optical device 100n shown in FIG. 11(a). FIG. 12 is a schematic diagram for illustrating a configuration of another optical device 100p according to the fifth embodiment. In optical device 100n shown in FIG. 11(a), condenser 90 is formed from the multilayer ceramic condenser, however, it is noted that the capacitor is not limited thereto. An example in which a semiconductor capacitor is adopted as the capacitor in optical device 100p shown in FIG. 12 will be described. Moreover, the type of the condenser is not limited as such. Features of optical device 100p shown in FIG. 12 that are the same as those of optical device 100n shown in FIG. 11(a) have the same reference characters allotted and detailed description will not be repeated.

Optical device 100p shown in FIG. 12 includes a substrate 10b within which a condenser 91, which is a capacitor, is arranged, optical element 20 placed on an outer surface of substrate 10b, and semiconductor switch 30a. Condenser 91 is a power supply condenser and implemented by a semiconductor capacitor. Condenser 91 is formed from an N+ layer 15a, a dielectric layer 13a formed thereon, and a polysilicon layer 14a. N+ layer 15a is formed in a semiconductor process by implanting n-type impurity ions into a silicon substrate 18. According to exemplary aspects, dielectric layer 13a can be composed of an inorganic material such as silicon oxide, silicon nitride, hafnium oxide, hafnium silicate, alumina, or barium titanate and formed, for example, by chemical vapor deposition (CVD). Polysilicon layer 14a is composed of a conductor and formed on a surface of dielectric layer 13a with CVD. Though silicon substrate 18 is described as a substrate where condenser 91 is formed, a substrate such as a sapphire substrate or a GaAs substrate may be applicable.

N+ layer 15a is a low-resistance layer formed by providing a plurality of trenches or a plurality of pillars in silicon substrate 18 to form projecting and recessed shapes and implanting n-type impurity ions into surfaces of the formed projecting and recessed shapes at a high concentration. This configuration increases an area of dielectric layer 13a lying between N+ layer 15a and polysilicon layer 14a to increase a capacitance of the condenser. Therefore, the number or a size of trenches or pillars formed in silicon substrate 18 is designed in conformity with magnitude of the capacitance necessary for condenser 91. The configuration of condenser 91 is by way of example and not limited to the above. Though dielectric layer 13a is described as being formed from a single layer with reference to FIG. 12, it may be formed from a plurality of layers composed of an identical material or of different materials. Though an example in which N+ layer 15a is formed in condenser 91 by implanting n-type impurity ions into silicon substrate 18 is described, a P+ layer may be formed by implanting p-type impurity ions into silicon substrate 18 depending on circuitry or a manufacturing process.

Polysilicon layer 14a serves as one electrode (a first internal electrode) that forms a capacitance of condenser 91. By forming a metal layer 14b on polysilicon layer 14a, resistivity of one electrode formed from polysilicon layer 14a is lowered. So long as necessary resistivity is obtained only by polysilicon layer 14a, metal layer 14b does not have to be formed. Polysilicon layer 14a on which metal layer 14b is formed is electrically connected to interconnection 46 through a via conductor 16a. Though one electrode (first internal electrode) that forms the capacitance of condenser 91 is formed from polysilicon layer 14a, the electrode may be formed from a metal layer.

Moreover, in the exemplary aspect, N+ layer 15a serves as the other electrode (a second internal electrode) that forms a capacitance of condenser 91. N+ layer 15a is electrically connected to interconnection 47 through a via conductor 17a.

Interconnections 46 and 47 are electrodes for placement of optical element 20 and semiconductor switch 30a on the outer surface of condenser 91. Specifically, in condenser 91 shown in FIG. 12, interconnection 46 is formed on the outer surface on the left on the sheet plane and interconnection 47 is formed on the outer surface on the right on the sheet plane. A gate drawn electrode (not shown) and interconnection 48 are formed on the outer surface of condenser 91 between interconnections 46 and 47.

Moreover, optical element 20 has one electrode (for example, the anode) connected to interconnection 46 and has the other electrode (for example, the cathode) electrically connected to interconnection 21. Optical element 20 and interconnection 48 are electrically connected to each other through interconnection 21.

Semiconductor switch 30a has one electrode (for example, the drain electrode) connected to interconnection 48 and has the other electrode (for example, the source electrode) electrically connected to interconnection 47. The circuitry of optical device 100p is as shown in FIG. 11(b).

Conductive pillar 50, which is a conductive pillar member, is provided on interconnection 47 and conductive pillar 51, which is a conductive pillar member, is provided on interconnection 46. Conductive pillars 50 and 51 are provided substantially perpendicularly to the surface of substrate 10b and provided at positions where they do not cut off the optical path of optical element 20. In conductive pillars 50 and 51, electrodes 60 and 61 for electrical connection to an external circuit board are formed on surfaces opposite to surfaces thereof connected to interconnections 47 and 46, respectively. Electrodes 60 and 61 are formed, for example, by plating or vapor deposition on respective one surfaces of conductive pillars 50 and 51. In optical device 100p, the surface of substrate 10b where optical element 20 is placed is sealed with molding member 70.

As set forth above, in optical devices 100n and 100p according to the fifth embodiment, a capacitor is arranged in the inside of each of substrates 10a and 10b. In particular in optical device 100p, substrate 10b is a silicon substrate (semiconductor substrate) and the capacitor is a semiconductor capacitor including in substrate 10b, dielectric layer 13a as well as polysilicon layer 14a (first internal electrode) and N+ layer 15a (second internal electrode) arranged with dielectric layer 13a being interposed. Thus, optical device 100p can be mounted on the circuit board with conductive pillars 50 and 51 provided on substrate 10b being interposed. Therefore, a through hole or a via that passes through substrate 10b from the upper surface to the lower surface does not have to be provided, manufacturing cost can be reduced, and lowering in mechanical strength of substrate 10b can be avoided.

In the semiconductor capacitor, dielectric layer 13a is formed in a direction perpendicular to the surface of substrate 10b where optical element 20 and semiconductor switch 30a are placed. In other words, the semiconductor capacitor is in such a structure that a low-resistance layer is formed by providing a plurality of trenches or a plurality of pillars in silicon substrate 18 and implanting n-type impurity ions into the plurality of provided trenches or pillars at a high concentration and dielectric layer 13a is formed on the surface of the low-resistance layer as lying between polysilicon layer 14a (first internal electrode) and N+ layer 15a (second internal electrode). In this configuration, condenser 91 formed from a semiconductor capacitor secures a capacitance value by being provided with a portion with projecting and recessed shapes as in FIG. 12.

### Sixth Exemplary Embodiment

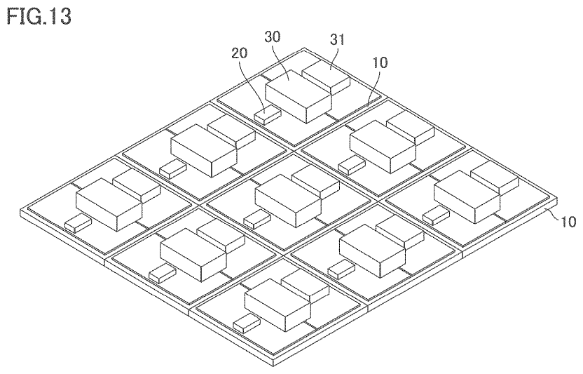

A manufacturing method in manufacturing a plurality of optical devices 100c shown in FIG. 2(b) will be described in the present embodiment. Initially, FIG. 13 is a schematic diagram showing a step of placing an optical element on a substrate in the method of manufacturing an optical device according to the sixth embodiment. A surface of substrate 10 shown in FIG. 13 is divided, for example, into 3×3 regions, an interconnection (not shown) is formed in each region, and optical element 20, semiconductor switch 30, and control IC 31 are placed on the interconnection. A capacitor (not shown) is arranged on or in the inside of substrate 10.

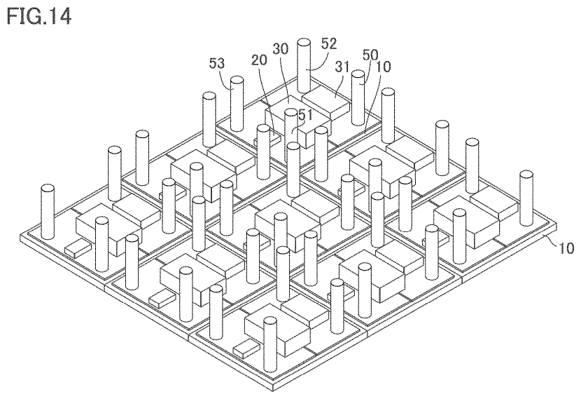

Then, FIG. 14 is a schematic diagram showing a step of providing a conductive pillar on the substrate in the method of manufacturing an optical device according to the sixth embodiment. In each region of substrate 10 shown in FIG. 14, conductive pillars 50 to 53 are provided at four corners thereof. Conductive pillars 50 to 53 are implemented by metal pins each formed in a columnar shape and electrically connected to a part of the interconnection.

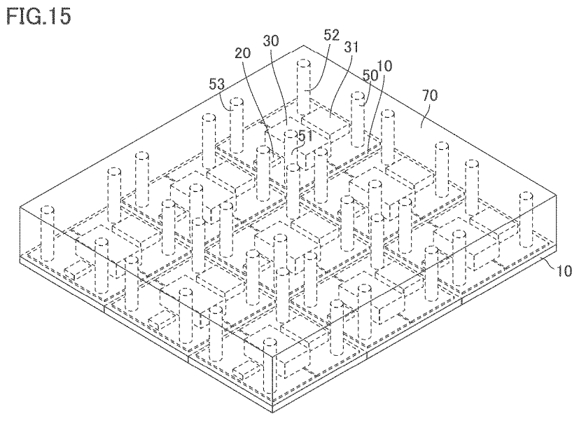

Then, FIG. 15 is a schematic diagram showing a step of sealing a surface of the substrate with molding member 70 in the method of manufacturing an optical device according to the sixth embodiment. In particular, optical element 20 and the like placed in each region are sealed with molding member 70 by covering the entire surface of substrate 10 shown in FIG. 15 with molding member 70.

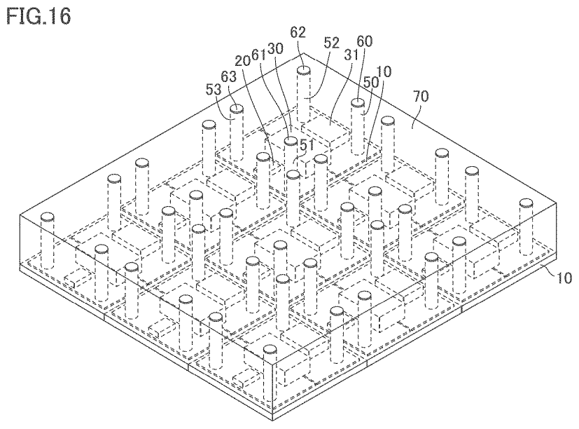

Then, FIG. 16 is a schematic diagram showing a step of forming an electrode on a surface of molding member 70 in the method of manufacturing an optical device according to the sixth embodiment. One surface of each of conductive pillars 50 to 53 is exposed by polishing the surface of molding member 70 shown in FIG. 16. One exposed surfaces of conductive pillars 50 to 53 are plated to form electrodes 60 to 63.

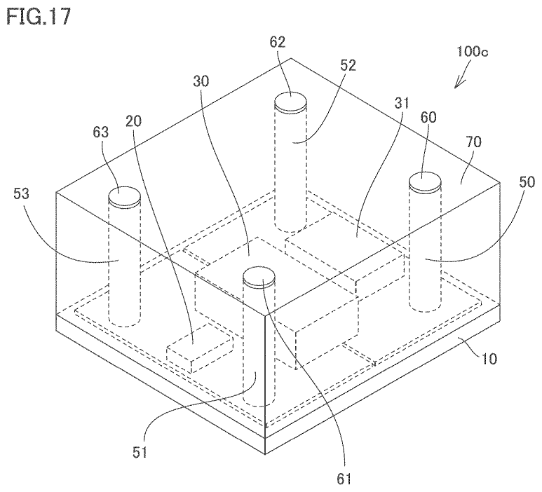

Then, FIG. 17 is a schematic diagram showing a step of dicing into optical devices in the method of manufacturing an optical device according to the sixth embodiment.

Optical device 100c shown in FIG. 17 is one diced device resulting from dicing of substrate 10 shown in FIG. 16 into 3×3 devices by a dicing plate or the like.

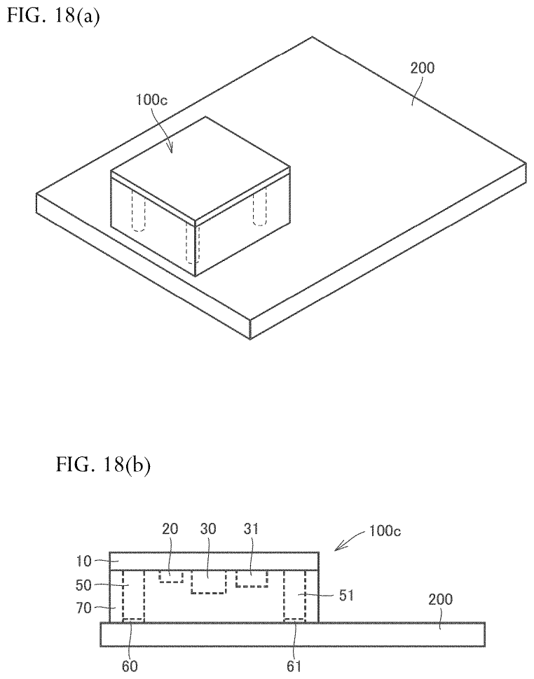

Then, FIGS. 18(a) and 18(b) are schematic diagrams showing a step of mounting the optical device on a circuit board in the method of manufacturing an optical device according to the sixth embodiment. FIG. 18(a) is a perspective view of optical device 100c mounted on a circuit board 200 and FIG. 18(b) shows a side view of optical device 100c mounted on circuit board 200. As shown in FIG. 18(b), optical device 100 is mounted on circuit board 200 by flip-chip mounting to connect electrodes 60 and 61 to the circuit board. Since conductive pillars 50 to 53 are larger in height from substrate 10 at least than optical element 20, optical element 20 is not in contact with the circuit board in spite of flip-chip mounting of optical device 100 on circuit board 200.

As set forth above, the method of manufacturing an optical device according to the sixth embodiment includes forming interconnections on substrate 10 where a plurality of capacitors are arranged and placing a plurality of optical elements 20 at prescribed positions on substrate 10 and electrically connecting the plurality of optical elements 20 and the plurality of capacitors to each other through the interconnections. The method of manufacturing an optical device further includes forming one or more conductive pillars 50 to 53 being larger in height from substrate 10 at least than the plurality of optical elements and electrically connected to parts of the interconnections, forming electrodes 60 to 63 electrically connected to circuit board 200 on surfaces of one or more conductive pillars 50 to 53 opposite to surfaces thereof connected to the parts of the interconnections, and dicing substrate 10 such that the diced substrate includes one of the plurality of optical elements 20.

The optical device manufactured with the manufacturing method according to the sixth embodiment can thus be reduced in size because it can be mounted on the circuit board with at least one conductive pillar 50, 51 being interposed, at least one conductive pillar 50, 51 being larger in height from substrate 10 at least than optical element 20 and electrically connected to a part of the interconnection.

In the step of providing conductive pillars 50 to 53 on substrate 10 shown in FIG. 14, the conductive pillars may be provided by arranging metal pins each formed in a columnar shape at prescribed positions or by plating.

### (Additional Modifications)

(1) Condenser 91 according to the fifth embodiment is described as being a semiconductor capacitor with projecting and recessed shapes. Without being limited as such, in the semiconductor capacitor, internal electrodes and a dielectric layer lying between the internal electrodes may be formed from flat plates in parallel to one another in an additional exemplary aspect.
(2) Optical device 100p according to the fifth embodiment is described as including optical element 20 and semiconductor switch 30a placed on the outer surface of condenser 91. Without being limited as such, in adopting a semiconductor capacitor for the capacitor, semiconductor switch 30a may be integrated with the semiconductor capacitor in an additional exemplary aspect.
(3) In optical device 100p according to the fifth embodiment, an interconnection on which optical element 20 and semiconductor switch 30a are to be placed is described as being formed on an insulating film 19 composed of an inorganic material such as silicon oxide or silicon nitride on the outer surface of condenser 91. Without being limited as such, an interconnection where optical element 20 and semiconductor switch 30a are to be placed may be formed in a rewiring step in an additional exemplary aspect.
(4) The optical devices according to the embodiments described previously are described as including optical element 20, semiconductor switch 30, 30a, and control IC 31 as elements to be placed on the surface of the substrate. Without being limited as such, any element may be mounted on the surface of the substrate in an additional exemplary aspect.
(5) The optical devices according to the embodiments described previously are described as including four conductive pillars in a single optical device. Without being limited as such, the number of conductive pillars to be provided in a single optical device may be modified depending on a structure of the optical device or a portion of connection to the circuit board. It is noted that at least one conductive pillar should be provided in the optical device.

### REFERENCE SIGNS LIST

10, 10a, 10b, 11, 12 substrate; 11b internal interconnection; 12b through hole; 13 dielectric ceramic layer; 13a dielectric layer; 14, 15 internal electrode; 14a polysilicon layer; 14b metal layer; 15a layer; 16, 16a, 17, 17a via conductor; 18 silicon substrate; 19 insulating film; 20 optical element; 21, 40 to 43, 46 to 48, 82, 83 interconnection; 22 light emitter; 30, 30a semiconductor switch; 32 optical component; 50, 51, 84, 85 conductive pillar; 70, 71, 72 molding member; 80, 81 wire; 90, 91 condenser; 100 optical device; 200 circuit board

1. An optical device mountable on a circuit board, the optical device comprising:
a substrate having a capacitor arranged on or in inside the substrate;
at least one optical element disposed on the substrate;
an interconnection disposed on the substrate, with the capacitor being electrically connected to the optical element through the interconnection;
at least one conductive pillar having a height from the substrate that is larger than the optical element and that is electrically connected to the interconnection; and
an electrode disposed on a surface of the at least one conductive pillar opposite to a surface coupled to the interconnection, with the electrode being constructed to electrically connect to the circuit board.

2. The optical device according to claim 1, further comprising a molding member disposed on a surface of the substrate to cover the optical element and the at least one conductive pillar.

3. The optical device according to claim 2, wherein the molding member is configured through which a wavelength of light emitted or received by the optical element passes at least on an optical path of the light.

4. The optical device according to claim 2, wherein the molding member is transparent to a wavelength of light emitted or received by the optical element.

5. The optical device according to claim 1, further comprising:
at least one of a switching element disposed on the substrate and configured to control a power feed to the optical element; and
a control element disposed on the substrate and configured to control light emission by the optical element.

6. The optical device according to claim 1, further comprising an optical component disposed on the substrate and configured to change an optical path of light emitted or received by the optical element.

7. The optical device according to claim 1, wherein the at least one conductive pillar is directly electrically connected through a wire to the optical element.

8. The optical device according to claim 1, wherein the at least one conductive pillar is partially directly electrically connected to the optical element.

9. The optical device according to claim 1, wherein the at least one conductive pillar includes a portion different in cross-sectional shape in a surface in parallel to a surface of the substrate.

10. The optical device according to claim 1, wherein the at least one conductive pillar is partially disposed in a recess or a through hole extending in the substrate.

11. The optical device according to claim 1, wherein a part of the substrate extends to a same height as the at least one conductive pillar, and an electrode formed in the part of the substrate is electrically connected to the optical element through an internal interconnection disposed within the substrate.

12. The optical device according to claim 2, wherein the molding member comprises a plurality of layers, and an in-mold interconnection electrically connected to the at least one conductive pillar is disposed between a pair of layers of the plurality of layers.

13. The optical device according to claim 1, wherein the substrate is a semiconductor substrate, and the capacitor is a semiconductor capacitor included in the substrate.

14. The optical device according to claim 13, further comprising a dielectric layer and first and second internal electrodes disposed with the dielectric layer interposed therebetween.

15. The optical device according to claim 1, wherein each of the optical element and the at least one conductive pillar are directly disposed on the interconnection.

16. A method of manufacturing an optical device mountable on a circuit board, the method comprising:
forming an interconnection on a substrate with a plurality of capacitors being arranged on or in inside the substrate;
disposing a plurality of optical elements at prescribed positions on the substrate and electrically connecting the plurality of optical elements to the plurality of capacitors, respectively, through the interconnection;
forming at least one conductive pillar that has a height from the substrate that is larger than the plurality of optical elements and that is electrically connected to the interconnection;
forming an electrode on a surface of the at least one conductive pillar opposite to a surface connected to the interconnection, with electrode configured to electrically connect to the circuit board; and
dicing the substrate such that each diced substrate includes one of the plurality of optical elements.

17. The method according to claim 16, further comprising forming a molding member on a surface of the substrate to cover the optical element and the at least one conductive pillar.

18. The method according to claim 16, further comprising:
forming a switching element on the substrate that is configured to control a power feed to the optical element; and
forming a control element on the substrate that is configured to control light emission by the optical element.

19. The method according to claim 16, further comprising forming the at least one conductive pillar to be partially disposed in a recess or a through hole extending in the substrate.

20. The method according to claim 16, further comprising forming an optical component on the substrate that is configured to change an optical path of light emitted or received by the optical element.
